(19) United States
(12) Patent Application Publication
(10) Pub. No.: US 2022/0009947 A1
(43) Pub. Date: Jan. 13, 2022

(54) CUPROUS CYSTEAMINE OPTICAL MATERIALS FOR VISIBLE LIGHT ENHANCEMENT

(71) Applicant: BOARD OF REGENTS, THE UNIVERSITY OF TEXAS SYSTEM, Austin, TX (US)

(72) Inventor: Wei Chen, Austin, TX (US)

(21) Appl. No.: 17/371,453

(22) Filed: Jul. 9, 2021

Related U.S. Application Data
(60) Provisional application No. 63/050,324, filed on Jul. 10, 2020.

(51) Int. Cl. C07F 1/08; A01G 7/04; H01L 33/50

(52) U.S. Cl. CPC C07F 1/08; G01N 21/64; H01L 33/504; A01G 7/045

(57) ABSTRACT

Disclosed herein are composite materials that comprise one or more copper-cysteamines capable of converting higher frequency, lower wavelength radiation into visible light. As used, the produced visible light enhances the amount of visible light already present from natural or artificial sources.

### FIELD

Disclosed herein are composite materials that comprise one or more copper-cysteamines capable of converting higher frequency, lower wavelength radiation into visible light. As used, the produced visible light enhances the amount of visible light already present from natural or artificial sources.

### BACKGROUND

It is projected that the world population will be about 10 billion before reaching a plateau in the later part of this century and increasing economic prosperity of the developing world is forecast to soon place even greater demands on agricultural production than will population growth. With very few prospects to sustainably expand the 1.5 billion ha of cropland currently under cultivation, a doubling of productivity will be needed to meet the increasing demand before the end of this century. In the last ten years, increases in yield for some major crops such as rice have shown little improvement. In 2008, the world saw the lowest wheat stockpiles of the past 30 years and fears of a rice shortage incited riots in some countries. Adding to this, the rapid growth in the Chinese and Indian economies has resulted in never before seen demands on grain supplies. Increasing grain crop productivity is the foremost challenge facing agricultural research. Globally, rice is the world's most important crop in terms of the number of people who depend upon it as their major source of calories and nutrition. After rapid increases in yield over the latter half of the twentieth century, further yield increases appear harder to obtain. This indicates that human will be facing the crisis of food supplies in the near future and a boost in food production is urgently demanded.

The other challenge facing the world is an energy crisis. Our present oil reserves will last 40 years at most and will decline significantly well before then. Globally, experts are working hard to find out how renewable sources of energy can be used to better fulfill our energy needs. Today, when we talk about renewable energy resources we usually mean solar energy, wind power and water (hydroelectric or watermill) power. Renewable energy sources by their very nature will never be exhausted. The great thing about solar energy is that there is an unlimited supply and it is relatively easy and straightforward to implement. Solar energy does not pollute the environment and produces so much energy that the total amount of light and heat energy that hits the earth every hour is enough to meet the entire energy needs of the planet for a whole year. The use of copper-cysteamine (Cu-Cy) nanoparticle photosensitizers having tunable optical properties to convert UV sunshine to blue and red light for photosynthesis improvement can provide a good solution not only for food need but also for other purposes that will help with the energy crisis. Numerous efforts have been dedicated to the research and development of luminescence materials for these applications and most phosphors are rare earth-based materials. For example, the three basic phosphors for solid-state lighting are materials doped with Eu³⁺ (red), Tb³⁺ (green) and Eu²⁺ (blue). The most tested luminescence or light converting materials for photosynthesis improvement are Eu²⁺ doped sulfates and silicate phosphors. The advantage is that these materials have a high light output that can meet the requirement for these applications. However, the challenging issue is that rare earths are very expensive and their resources are limited due to the extremely low abundance of these elements on earth.

There is, therefore, a long felt need for alternative solutions. One alternative is the use of the disclosed copper-cysteamines that can fulfill these requirements of practical applications, an alternative that is inexpensive, practical, and provides near to equal or better results when compared to the rare earth phosphors.

### BRIEF DESCRIPTION OF THE FIGURES

FIG. 1 is the infrared spectrum of the disclosed copper-cysteamines (Cu-Cy-X) wherein X is fluorine, chlorine, bromine and iodine.

FIGS. 2A-2C depict the photophysical properties of the disclosed copper-cysteamine nanoparticles wherein X is halogen. FIG. 2A depicts the UV-vis absorption spectra of Cu-Cy-X at room temperature dispersed in DI water. FIG. 2B depicts the emission (right) and excitation spectra (left) of Cu-Cy-X suspended in DI water at room temperature. FIG. 2C depicts the emission decay curves of Cu-Cy-X.

FIG. 3A is an EPR spectra of Cu-Cy-X wherein X is chlorine, bromine and iodine dispersed in deionized water at 3 mg/mL, (30 μL) and TEMP (0.1 mol/L. 30 μL) under irradiation of 360-370 nm UV light for 10 minutes versus control.

FIG. 3B is the RNO absorption quenched by singlet oxygen produced by the 3 Cu-Cy-X species of FIG. 3A under UV irradiation.

FIG. 4 is the XRD patterns of the disclosed Cu-Cy-X's

FIGS. 5A-5C are EDS images of the disclosed Cu-Cy-X's with elemental analysis as an insert. FIG. 5A is X═Cl. FIG. 5B is X═Br. FIG. 5C is X═I.

FIGS. 6A-6C are the luminescence decay curves for the disclosed Cu-Cy-X's. FIG. 6A is Cu-Cy-Cl1, FIG. 6B is Cu-Cy-Br and FIG. 6C is Cu-Cy-I. A double exponential decay equation fits the decay curve very well and the solid lines are the double exponential fitting curve of the lifetimes

FIGS. 7A-7C are SEM images of the disclosed compounds. FIG. 7A is Cu-Cy-Cl, FIG. 7B is Cu-Cy-Br, and FIG. 7C is Cu-Cy-I.

FIGS. 8A-8C are TEM images of the disclosed compounds. FIG. 8A is Cu-Cy-Cl, FIG. 8B is Cu-Cy-Br, and FIG. 8C is Cu-Cy-I.

FIG. 9 is an EDS spectrum of Cu-Cy-I.

FIGS. 10A-10C are ball and stick representations of Cu-Cy crystals unit cell.

FIG. 10A is Cu-Cy-Cl, FIG. 10B is Cu-Cy-Br and FIG. 10C is Cu-Cy-I.

### DETAILED DESCRIPTION

The materials, compounds, compositions, articles, and methods described herein may be understood more readily by reference to the following detailed description of specific aspects of the disclosed subject matter and the Examples included therein.

Before present materials, compounds, compositions, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

All percentages, ratios and proportions herein are by weight, unless otherwise specified. All temperatures are in degrees Celsius (°C) unless otherwise specified.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, an apparatus that “comprises,” “has,” “includes” or “contains” one or more elements possesses those one or more elements, but is not limited to possessing only those elements. Likewise, a method that “comprises,” “has,” “includes” or “contains” one or more steps possesses those one or more steps, but is not limited to possessing only those one or more steps.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that when a value is disclosed, then “less than or equal to” the value, “greater than or equal to the value,” and possible ranges between values are also disclosed, as appropriately understood by the skilled artisan. For example, if the value “10” is disclosed, then “less than or equal to 10” as well as “greater than or equal to 10” is also disclosed. It is also understood that throughout the application data are provided in a number of different formats and that this data represent endpoints and starting points and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

The terms “a” and “an” are defined as one or more unless this disclosure explicitly requires otherwise. Ranges may be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values expressed as “greater than” do not include the lower value. For example, when the “variable x” is defined as “greater than zero” expressed as “0 <x” the value of x is any value, fractional or otherwise that is greater than zero. Similarly, values expressed as “less than” do not include the upper value. For example, when the “variable x” is defined as “less than 2” expressed as “x<2” the value of x is any value, fractional or otherwise that is less than 2.

“Optional” or “optionally” means that the subsequently described event or circumstance can or cannot occur, and that the description includes instances where the event or circumstance occurs and instances where it does not

Any embodiment of any of the apparatuses, systems, and methods can consist of or consist essentially of—rather than comprise/include/contain/have—any of the described steps, elements, and/or features. Thus, in any of the claims, the term “consisting of” or “consisting essentially of” can be substituted for any of the open-ended linking verbs recited above, in order to change the scope of a given claim from what it would otherwise be using the open-ended linking verb.

The feature or features of one embodiment may be applied to other embodiments, even though not described or illustrated, unless expressly prohibited by this disclosure or the nature of the embodiments.

Any embodiment of any of the apparatuses, systems, and methods can consist of or consist essentially of—rather than comprise/include/contain/have—any of the described steps, elements, and/or features. Thus, in any of the claims, the term “consisting of or “consisting essentially of can be substituted for any of the open-ended linking verbs recited above, in order to change the scope of a given claim from what it would otherwise be using the open-ended linking verb. The feature or features of one embodiment may be applied to other embodiments, even though not described or illustrated, unless expressly prohibited by this disclosure or the nature of the embodiments.

As used herein, “electromagnetic radiation” refers to a form of energy containing both electric and magnetic wave components which includes ultraviolet (UV), visible and infrared (IR) radiation.

As used herein, “plant” or “plants” can be used interchangeably with the term “crops” which refers to grains, such as rice, wheat, barley, oats, soy beans, rye, spelt, corn, millet, sorghum, buckwheat, chia, quinoa, chickpeas, lentils, lima beans, peanuts, rapeseed, flax seed, and the like. Plant further refers to non-edible plants, for example, flowers, hay and the like.

The feature or features of one embodiment may be applied to other embodiments, even though not described or illustrated, unless expressly prohibited by this disclosure or the nature of the embodiments.

The disclosed compounds and compositions can be used to enhance the photosynthesis by bacteria, fungi and photosynthetic eukaryotic organisms such as algae that use water and CO₂ to make ethanol.

The disclosed materials can be a primary method for light conversion, for example, for enhancing lighting through windows and for detection or sensing purposes. Without wishing to be limited by theory, UV detection can be difficult. However, when UV is converted to visible light which is easy for detection. This can be used for UV detection and high energy particles or rays detection. UV light is harmful to human being if dose is high and UV light is not easy to pass through glass windows. However, by converting UV light to visible light, it can enhance window lighting which is beneficial in cloudy weathers from living rooms, cars, trains and airplanes,

One aspect of the disclosure relates to novel copper cysteamine compounds having the formula:

Cu₃X(SR)₂

wherein R is —CH₂CH₂NH₂; and
X is chosen from Cl, Br, or I.

A further aspect of the disclosure relates to composites, comprising:
a) one or more of the disclosed copper cysteamine compounds; and
b) a substrate;
wherein the copper cysteamine compounds are positioned within the substrate.

In one aspect the disclosed composites, comprise:
a) two or more compounds having the formula:

Cu₃X(SR)₂
wherein R is —CH₂CH₂NH₂; and X is chosen from Cl, Br, or I; and
b) a substrate.

In another aspect, the disclosed composites, comprise:
a) two or more compounds having the formula:

Cu₃X(SR)₂
wherein R is —CH₂CH₂NH₂; and X is chosen from Cl, Br, or I; and
b) a substrate;
wherein a first copper cysteamine emits visible light in the range of from about 520 nm to about 700 nm when exposed to UV radiation; and
a second copper cysteamine emits visible light in the range of from about 400 to about 520 nm when exposed to UV radiation.

In a still further aspect, relates to compositions, comprising:
a) two or more compounds having the formula:

Cu₃X(SR)₂
wherein R is —CH₂CH₂NH₂; and X is chosen from Cl, Br, or I; and
b) one or more adjunct ingredients.

The disclosed composite materials provide a source of strong white light that can be used for solid-state lighting, full color displays, and as a light source for plant growth, crop improvement and interior lighting. The disclosed materials can have any form chosen by the formulator, for example, films, transparent solid shapes, semi-transparent solid shapes, or a transparent shaped-solid that has one or more reflective surfaces on the inside of the material or on portions of the outside surface.

In one aspect the disclosed composite material is a film. In another aspect the composite material is in the form of a transparent solid. In a further aspect the disclosed composite material is in the form of a semi-transparent solid. Each of these aspects is capable of converting sources of electromagnetic radiation in the ultraviolet range, or above, into electromagnetic radiation in the visible range (i.e., visible light). This ability applies to either natural sources, i.e., direct sunlight, or artificial ultraviolet sources.

For the purposes of the present disclosure, visible light is divided into an upper visible light range (400-520 nm) range and a lower visible light range (520-700 nm). One aspect of the disclosure comprises at least two compounds that when excited by X-ray or

UV light produces visible light in both the upper range and lower range. In certain aspects, however, the composite is only be required to emit light in either the upper of lower range.

In one aspect disclosed are visible light enhancing compositions, comprising:
i) a first copper-cysteamine that emits visible light in the range of from about 520 nm to about 700 nm when exposed to UV radiation; and
ii) a second copper-cysteamine that emits visible light in the range of from about 400 to about 520 nm when exposed to UV radiation;
thereby providing an enhancement in the amount of visible light.

In a further aspect disclosed herein are compositions, comprising a copper-cysteamine that emits visible light in the range of from about 520 nm to about 700 nm when exposed to UV radiation.

In another aspect disclosed herein are compositions, comprising a copper-cysteamine that emits visible light in the range of from about 400 nm to about 520 nm when exposed to UV radiation.

The disclosed compositions comprise copper-cysteamines that are in the form of nanoparticles. As used herein, the term “copper-cysteamine” means a substance that exhibits the phenomenon of luminescence when irradiated by electromagnetic radiation. The disclosed copper-cysteamines emit electromagnetic radiation in specific ranges of visible light. Combinations of copper-cysteamines as disclosed herein, typically do not have emission peaks at the same wavelength, but can have some overlapping wavelengths. The disclosed copper-cysteamine nanoparticles can optionally comprise one or more rare earth elements.

Each of the composites described herein above, can further comprise other non-rare earth nanoparticles. One non-limiting example includes which CuS can be added to the composites to reduce heat and protect from infrared radiation damage.

### EXAMPLE 1

Preparation of Cu-Cy-X analogs

Cu-Cy-X analogs were synthesized using the method according to Chen et al. (Ma L et al. “A new Cu-cysteamine complex: structure and optical properties.” J Mater Chem C 2014; 2(21): 4239-4246 and Pandey N K et al. “A facile method for synthesis of copper-cysteamine nanoparticles and study of ROS production for cancer treatment.” J Mater Chem B (in press) 2019) with some modification.

General Synthesis

182 mg of CuCl₂.2H₂O, 254 mg of Cy.HCl, and 50 mL of DI water were mixed in a 250 mL of three-necked round bottom flask under the protection of nitrogen gas and stirred vigorously to obtain a colorless solution. Then, 1M of NaOH was added into the above solution until the color changed to light yellow with a pH 7. Once the color of the solution changed, 710 mg of KI was added into the reaction system and kept stirring until the color of the solution changed to colorless. Afterward, the whole reaction system was heated to 90° C. for about 15 min. Finally, the solution was cooled to room temperature under the inert environment. The product was then washed five times with the mixture of water and ethanol, and dried in a vacuum oven at 40° C. The yield of Cu-Cy-I was 74 mg, yield 44% (based on CuCl₂.2H₂O). The following amounts of other halogen CuCy analogs were obtained: Cu-Cy-Cl (71 mg), and Cu-Cy-Br (64 mg). These analogs were prepared under similar conditions, except that KI was replaced by KCl (319 mg), and KBr (510 mg), respectively.

Conditions for CuCy-I Synthesis

As a pre-cautionary note, when first synthesizing CuCy-I, it was found that the amount of KI used in the synthesis had a significant effect on the luminescence stability and particle size. When to molar ratio of CuCl₂.2H₂O: KI is 1:1 or 1:2, white suspended particles with yellow luminescence were formed. These particles however, were not stable, immediately oxidizing to a black solid when the inert gas blanketing the reaction vessel was removed. In addition, the particles when in solution were difficult to be centrifuged at 11000 rpm. Moreover, the fluorescence intensity of the suspended solution was quenched after irradiation with ultraviolet light of 365 nm.

When the molar ratio of CuCl₂.2H₂O:KI was adjusted to 1:4, stable and easily isolatable quantities of CuCy-I were obtained. The pH of the reaction solution was adjusted over a range and the optimal pH for CuCy-I formation was found to be pH about 7. Even at pH 7.5 degradation of the product was observed those particles having no luminescent properties.

### Characterization

Without wishing to be limited by theory the various halogen ions that comprise the disclosed nanoparticles have distinct properties of hard and soft bases, the isomorphic Cu-Cy-X with the formula of Cu₃X(SR)₂ possess tunable luminescence from orange to yellow and efficient generation ability of singlet oxygen. As such, it can be expected that Cu-Cy-Br and Cu-Cy-I are similar multifunctional sensitizers to Cu-Cy and are better sensitizer on the basis of singlet oxygen ability. The properties of the disclosed Cu-Cy-X nanoparticles are described herein below.

The Fourier transform infrared (FT-IR) spectra were obtained by a Fourier transform infrared spectroscopy analyzer (NEXUS/United States Renee) by using KBr pellets in the range of 400-4000 cm⁻¹. The X-ray diffraction (XRD) patterns with a 20 range from 5° to 80° were identified by the laboratory powder X-ray diffraction system (D8 ADVANCE) with Cu Kα radiation. The content of the three elements C, H, and N was measured using an elemental analyzer (VARIO EL CUBE/ELEMENTAR). The UV-VIS absorption and photoluminescence (PL) spectra of Cu-Cy-X suspension were measured using a Shimadzu UV-2450 UV-Vis spectrophotometer, a Shimadzu RF-5301PC fluorescence spectrophotometer, and a fluorescence spectrophotometer (F-4500/Hitachi, Japan). The scanning electron microscope (SEM) images were obtained using the FEI company's thermal field emission QUANTA Q400, and the US EDAX GENESIS spectrometer was used to obtain the mapping element distribution image and EDS data. The ultraviolet-visible diffuse reflectance spectra were conducted on an ultraviolet-visible diffuse reflectance spectrometer (U3310/Japan Shimadzu Corporation) with an integrating sphere attachment by using BaSO4 as the reference. ESR Spectroscopy was tested using JEOL (JES FA200/JEOL). The samples for ESR were prepared by mixing 30 μL of 3 mg/mL of Cu-Cy-X solution and 30 μL of 100 mM of 2,2,6,6-tetramethylpiperidine (TEMP). The fluorescence quantum efficiency (QY) and lifetime were obtained by using an ultraviolet-near-infrared steady transient fluorescence spectrometer (FLS980/Edinburgh Instruments) to select the appropriate excitation wavelength.

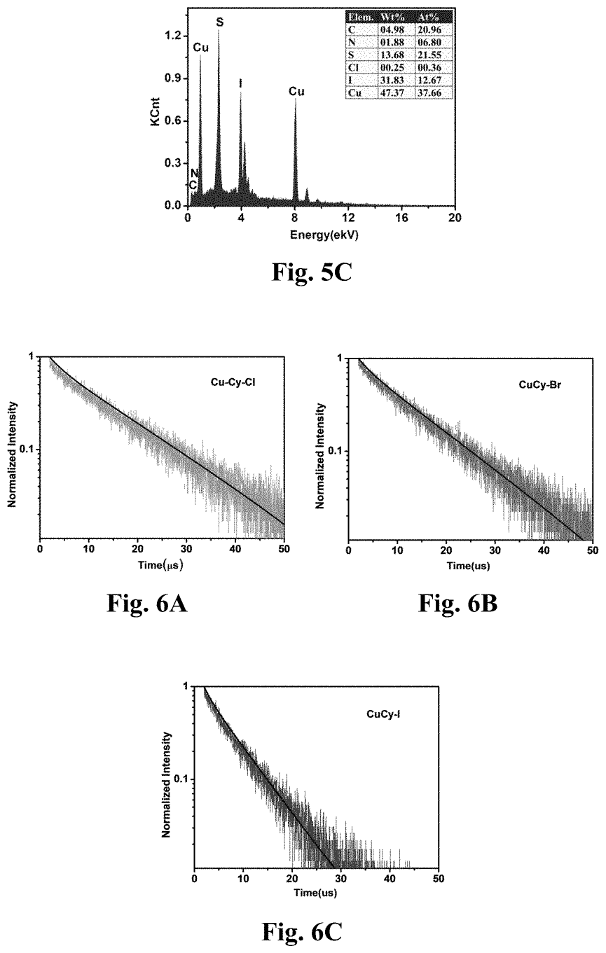

The EDS spectra (FIGS. 5A-5C) show that the mass percentages of chlorine in Cu-Cy-Br and Cu-Cy-I are very low, with 1.69% and 0.25%, respectively, indicating that Br⁻ and I⁻ successfully replaced the Cl⁻ of Cu-Cy. Overall, given the EDS analyses from FIGS. 5A-5C it can be summarized that Cu-Cy-Br is a 1.69 wt % Cl doped sample, whereas Cu-Cy-Cl and Cu-Cy-I are relatively purer samples.

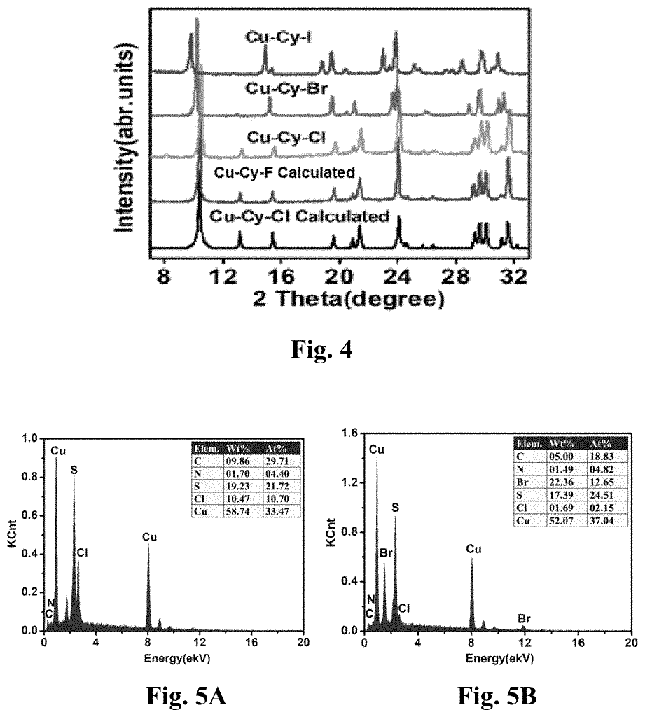

As shown in FIG. 4, the XRD spectra of as-synthesized Cu-Cy-Cl is in agreement with the simulated spectrum of reported Cu-Cy crystal. For Cu-Cy-Br and Cu-Cy-I, the peak shape is similar to that of Cu-Cy-Cl, but the position and the number of peaks have some shift and changes when compared with Cu-Cy-Cl (FIG. 4). The strongest peak of Cu-Cy-Cl at 2θ=10.42° is well matched with that of the simulated Cu-Cy, while the peak of Cu-Cy-Br and Cu-Cy-I shifts to 10.22° and 9.80° respectively due to expansion of lattices of Br and I containing cysteamines. Moreover, the triplet peaks of Cu-Cy-Br (19.53-21.04°) and Cu-Cy-I (18.82-20.43°) also display noticeable shift compared with the corresponding peaks of simulated Cu-Cy (19.62° -21.40°). Furthermore, the number of peaks in the Cu-Cy-Br and Cu-Cy-I changes. Cu-Cy-Br has two extra peaks at 15.60 and 15.37, while Cu-Cy-I has three peaks at 23.68, 23.49, and 23.01.

The X-ray diffraction patterns with a 2θ range from 5° to 80° were identified by the laboratory powder X-ray diffraction system (Rigaku Ultima IV) with Cu Ka radiation (λ=0.15406 nm) operated at 40 kV and 40 mA at a step size of 0.02°/sec.

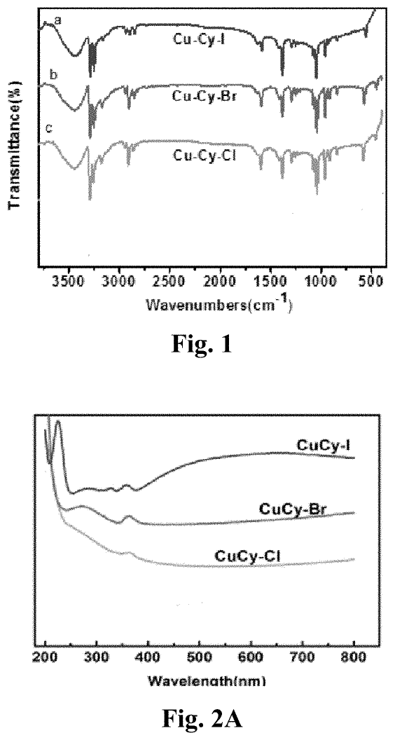

FIG. 1 shows that the FT-IR spectra of Cu-Cy-X are similar to each other, confirming the isomorphism of the compounds to some extent. In the spectra, the characteristic peaks of cysteamine dominate the FT-IR. The strong intensity peaks around 3300 cm⁻¹ should be assigned to the stretching vibration of N—H, while the peaks near 2900 cm⁻¹ belong to the vibration of C—H in methylene. The absence of weak absorption peaks around 2500 cm⁻¹ indicates that —SH group is deprotonated and coordinated to the cuprous atom. In addition, the absorption peaks of stretching vibration of Cu—X are 577 cm⁻¹ (Cu-Cy-F and Cu-Cy-Cl), 569 cm⁻¹ (Cu-Cy-Br) and 554 cm⁻¹ (Cu-Cy-I), respectively, which are consistent with the order of Cu-X bond strength, that is Cu-I>Cu-Br>Cu-Cl.

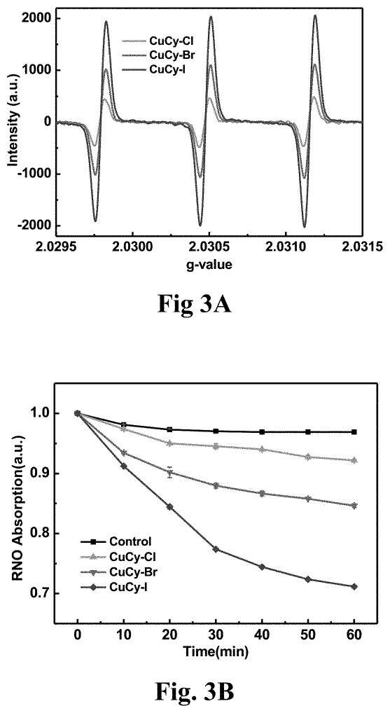

FIG. 3A is an EPR spectra of Cu-Cy-X wherein X is chlorine, bromine and iodine dispersed in deionized water at 3 mg/mL, (30 μL) and TEMP (0.1 mol/L. 30 μL) under irradiation of 360-370 nm UV light for 10 minutes. FIG. 3B is the RNO absorption quenched by singlet oxygen produced by the 3 Cu-Cy-X species of FIG. 3A under UV irradiation.

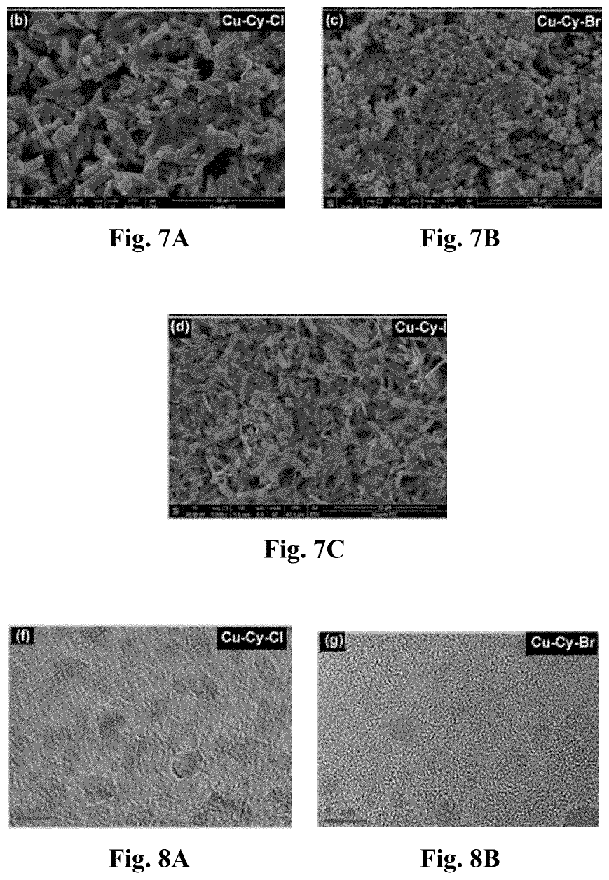

As depicted in the SEM images FIGS. 7A-7C, Cu-Cy-X samples are regular rectangular crystals with a wide range of particle size distribution, and most of the particles are micrometer range. Due to the uneven particle size, the samples in biological experiment and TEM test were handled as follows: the powder of Cu-Cy-X is dispersed in an appropriate amount of DI water to form suspension of 1 mg·mL⁻¹, following by ultrasonic for 60 min, centrifugation at 3000 rpm, discarding the large particles at the bottom, leaving the supernatant at 11000 rpm for further separation, and Cu-Cy-X nanoparticles were obtained.

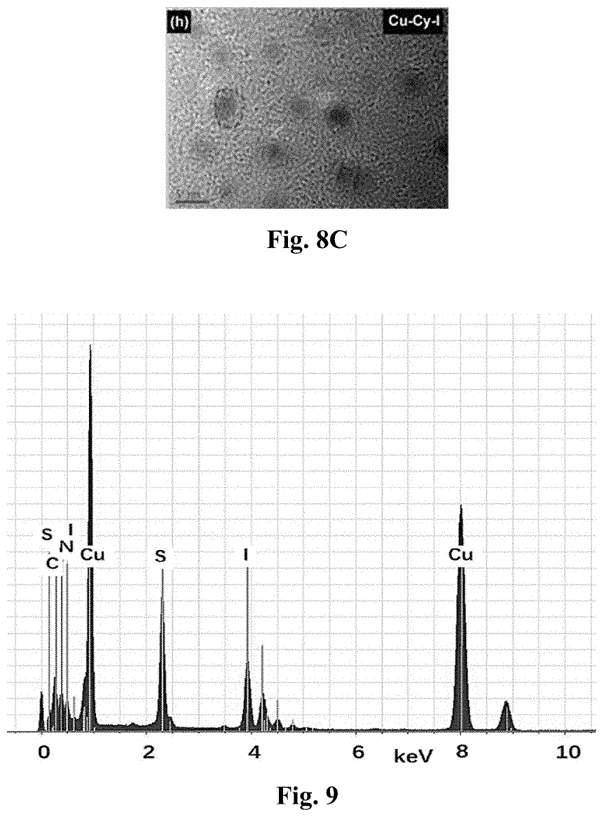

For the TEM images, n-hexane was used as the dispersant, which has a better dispersity to Cu-Cy-X than DI water. As depicted in FIGS. 8A-8C the TEM images of Cu-Cy-X particles collected from the supernatant after ultrasonic treatment shows nanometer size, less than 100 nm as well (FIG. 3e-h). To identify the nanoscale particles of Cu-Cy-X have the same composition as micron particles, we have measured the TEM mapping images by scanning particles with a size of about 100 nm. The results show that there are Cu, S, N, I and a small amount of Cl in the nanoparticle, which is consistent with the composition of Cu-Cy-I, indicating that the dispersed nanoparticle has no change in composition (Figure S8). In the EDS spectra of Cu-Cy-I nanoparticle, the characteristic absorption peaks of Cu, S, I, C and N are present, which further prove the nanoparticles and micro particles are same (Figure S9).

The content of the three elements C, H, and N (Table 1) was measured using an elemental analyzer (VARIO EL CUBE/ELEMENTAR).

TABLE 1

| | Sample | | | | | |
|---|---|---|---|---|---|---|
| | CuCy—Cl | | CuCy—Br | | CuCy—I | |
| Element | Calcd. | Found | Calcd. | Found | Calcd. | Found |
| C | 12.07 | 12.14 | 11.37 | 11.68 | 10.23 | 9.49 |
| N | 7.41 | 6.91 | 6.63 | 6.74 | 5.97 | 5.32 |
| H | 3.17 | 3.06 | 2.84 | 2.79 | 2.55 | 2.33 |

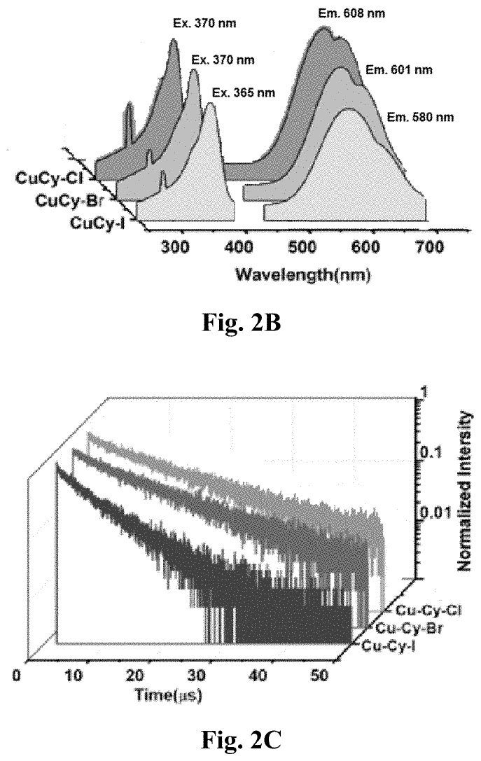

The absorption (FIG. 2A) and photoluminescence spectra of Cu-Cy-X suspension were measured using a Shimadzu UV-2450 UV-Vis spectrophotometer, a Shimadzu RF-5301PC fluorescence spectrophotometer and a fluorescence spectrophotometer (F-4500/Hitachi, Japan) SEM images were obtained using the FEI company's thermal field emission QUANTA Q400, and the US EDAX GENESIS spectrometer was used to obtain the mapping element distribution image and EDS data. The ultraviolet-visible diffuse reflectance spectra were conducted on an ultraviolet-visible diffuse reflectance spectrometer (U3310/Japan Shimadzu Corporation) with an integrating sphere attachment by using BaSO₄ as the reference. ESR Spectroscopy was tested using JEOL (JES FA200/JEOL). The sample for ESR was prepared by mixing 30 μL of 3 mg/mL CuCy-X solution and 30 μL of 100 mM TEMP. The fluorescence quantum efficiency (QY) and lifetime were obtained by using an ultraviolet-near-infrared steady transient fluorescence spectrometer (FLS980/Edinburgh Instruments) to select the appropriate excitation wavelength. The PL spectra of the disclosed Cu-Cy-X nanoparticles were measured under the excitation of 370 nm light for Cu-Cy-Cl, Cu-Cy-Br and 365 nm light for Cu-Cy-I with strong emission peaks at 608 nm for Cu-Cy-Cl, 601 nm for Cu-Cy-Br, and 580 nm for Cu-Cy-I (FIG. 2B). A blue shift of the emission peak of the sensitizers was observed and this trend is consistent with the order of the ligand-field strength of halogen atoms.

Without wishing to be limited by theory a reduced ligand-field strength of Cl<Br<I, the splitting energy of the d-orbitals decreases, which results in a larger energy level difference of HOMO-LUMO in Cu-Cy-X and a shorter emission wavelength (λₘₐₓ). As depicted in FIG. 2D, the emission decay curves of Cu-Cy-X are best fit to a double-exponential function and the lifetime (τ) are 12.15, 10.53 and 5.86 ,us for X═Cl, Br, and I respectively. The markedly reduced decay time of Cu-Cy-I compared to that of Cu-Cy-Cl and Cu-Cy-Br can be interpreted as the effect of the larger atomic number and the participation of the 5p orbital of iodide, which leads to stronger spin-orbit coupling (SOC) (FIGS. 6A-6C). Without wishing to be limited by theory SOC facilitates the rate of intersystem crossing (ISC) from the lowest exited singlet state (S₁) to the lowest triplet excited state (Ti), and so the increased rate of ISC of iodide makes a shorter decay time in Cu-Cy-I. The fact is further supported by the larger nonradiative rate constant of Cu-Cy-I with kₙᵣ=16.82×10⁴ s⁻¹ which is more than twice that of Cu-Cy-Cl and Cu-Cy-Br because the formula of emission lifetime can be expressed by equation (1):

τ⁻¹=kᵣ+kₙᵣ (1)

where kᵣ and kₙᵣ denote the radiative and nonradiative decay rate constant, respectively. Table 2 summarizes the main photophysical data of Cu-Cy-X in solid state at room temperature.

TABLE 2

| Compound | λ_{abs max}/nm | ^{a}λ_{em max}/nm | τ/μs | ^{b}Φ | ^{c}kᵣ/10⁴s⁻¹ | ^{c}kₙᵣ/10⁴s⁻¹ |
|---|---|---|---|---|---|---|
| Cu—Cy—Cl | 362 | 608 | 12.15 | 5.39% | 0.44 | 1.19 |
| Cu—Cy—Br | 272, 364 | 601 | 10.53 | 13.04% | 1.24 | 8.26 |
| Cu—Cy—I | 224, 358 | 580 | 5.86 | 8.34% | 1.42 | 16.82 |

^{a}λₑₓ = 375 nm;
^{b}λₑₓ = 370 nm for Cu—Cy—F, Cu—Cy—Cl, Cu—Cy—Br and λₑₓ = 365 nm for Cu—Cy—I;
^{c}kᵣ = Φ/τ;
^{d}kₙᵣ = (1-Φ)/τ.
All data were obtained in solid state at room temperature.

As seen in Table 2 the solid-state luminescence quantum yields (Φ) of Cu-Cy-X at room temperature is 5.39%, 13.04% and 8.34% for Cu-Cy-Cl, Cu-Cy-Br and Cu-Cy-I, which fall in the range of cuprous compounds having red emissions. The higher quantum yield of Cu-Cy-Br (13.04%) as compared to that of Cu-Cy-I (8.34%) indicates that halide ions have important roles on the photophysical properties of Cu-Cy-X (See, Vinogradova K A et al. Dalton Trans., 2014, 43, 2953-2960).

Photophysical properties of the disclosed Cu-Cy-X nanoparticles are illustrated in FIGS. 2A-2C. The four sensitizers have similar UV-vis absorption spectra with slight differences (FIG. 2A). The absorption bands in 200˜300 nm is ascribed to intra-ligand n→π* transitions of cysteamine (Cy), while low-energy absorption bands in the wavelength range from 300 to 400 nm are attributed to the MLCT and MC transition. Regarding the broad absorption bands between 400 and 800 nm for Cu-Cy-I, this band can be assigned to the large particle size and the electronic transition affected by the iodide ligand.

FIGS. 6A-6D are the luminescence decay curves for the disclosed Cu-Cy-X's. FIG. 6A is Cu-Cy-F, FIG. 6B is Cu-Cy-Cl, FIG. 6C is Cu-Cy-Br and FIG. 6D is Cu-Cy-I. A double exponential decay equation fits the decay curve very well and the solid lines are the double exponential fitting curve of the lifetimes. The stability of disclosed Cu-Cy-X nanoparticles was investigated under room temperature and pressure. When viewed by the naked eye the color of Cu-Cy-Cl and Cu-Cu-Br have changed to green and the luminescence intensity of them has decreased to some extent, while that of Cu-Cy-I had no discernable color change as observed by the naked eye. Without wishing to be limited by theory this phenomenon demonstrates that the Cu-Cy-I is more stable at ambient conditions and the Cu-Cy-Cl and Cu-Cy-Br are easier to dissociate and oxidize to produce a copper(II) compound.

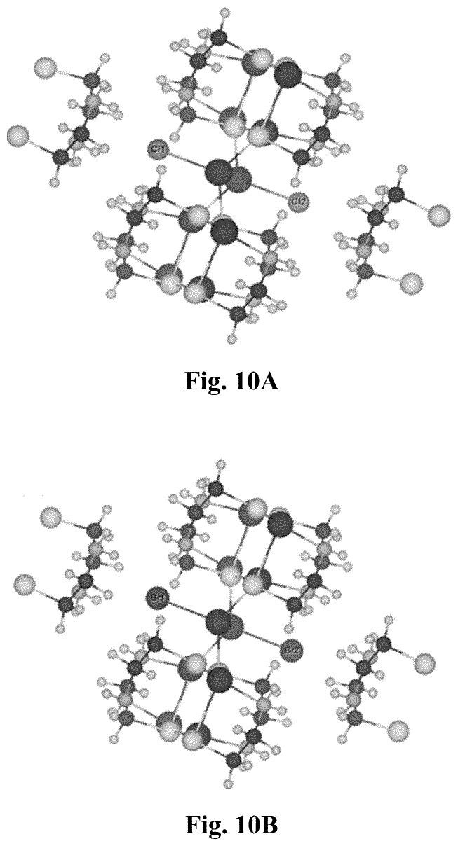

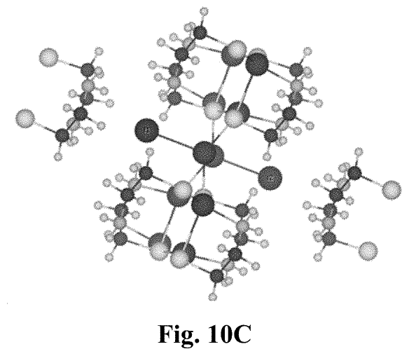

The lattice parameters and the angles are calculated theoretically of these materials by considering periodic structures of Cu-Cy-X (X═Cl, Br, and I) presented in FIGS. 10A-10C. These representations show the relaxed structures of FIG. 10A Cu-Cy-Cl, FIG. 10B Cu-Cy-Br, and FIG. 10C Cu-Cy-I where the unit cell of Cu-Cy-X has 8 atoms of C, 6 atoms of Cu, 24 atoms of H, 4 atoms of N, 4 atoms of S and 2 atoms of X (X═Cl, Br, and I). The unit cell shows that two different types of Cu atoms Cu(1), which is coordinated by two S atoms and X atom, and the second one Cu(2), which binds to 4 other atoms in the crystal, three S and one N.

### Preparation of Composites

As disclosed herein above, the composites which comprise the disclosed copper-cysteamines can convert UV radiation from an artificial or natural source into electromagnetic radiation in the visible range. Light efficiency for photosynthesis and interior light can be boosted by the use of a transparent or semi-transparent film wherein the disclosed copper-cysteamines are embedded therein. The film can comprise any polymer or polymer-like material, non-limiting examples of which include polyethylene, polyester, polyvinyl chloride, polystyrene, poly(methyl methacrylate), etc. The film can be placed on or sandwiched between other transparent materials. In addition to loading transparent polymer films the composites may be directly embedded into transparent materials for use in sunlight conversion.

The nanoparticles are combined with styrene in the desired amount after which an organic peroxide is added. The resulting admixture is sintered at 70° C. for 72 hours to provide a transparent film comprising the disclosed copper-cysteamines. The resulting polymeric film can be further processed by any conventional means.

For example, the copper-cysteamine/styrene admixture was heated and homogenized in an extruder screw until molten and evenly mixed. The admixture melt is forced through a flat extrusion die that presses the melt into the desired film shape. The thickness and strength of the film can further be affected by elongation rollers while the materials are still hot and pliable. The extruded film is then cooled, cut and packaged. The film transparency and luminescence properties as well as mechanical strength can be optimized by adjusting the particle loading concentration, size and surface coating.

Any monomer which results in a polymeric substrate that is capable of retaining the disclosed copper-cysteamines and allowing transmission of the emitted electromagnetic radiation is suitable for use. In addition to polystyrene, the following are non-limiting examples of suitable polymer for us as substrates: polystyrene, polyethylene, polyester, polyvinyl chloride, polystyrene, poly(methyl methacrylate), and the like.

In one aspect the composites are transparent. In one embodiment the copper-cysteamines are aligned along a first surface of a transparent substrate. In another embodiment the copper-cysteamines are aligned along a second transparent surface, and the first surface comprises a semi-transparent surface. In a further embodiment the copper-cysteamines are in the interior of the substrate. In one embodiment the first surface is transparent and captures natural or artificial UV radiation and the composite is configured such that the emitted enhanced visible light passes through the second semi-transparent surface to produce a muted glow.

In addition to the formation of a single transparent film comprising the disclosed copper-cysteamines, the copper-cysteamines can be embedded or supported by other transparent or semi-transparent substrates. Alternatively the copper-cysteamine embedded composites can be formed into geometric shapes. As such, all of the final polymeric composites can have a greater or lesser degree of flexibility depending upon the choice of the type of polymer, the amount of polymer, the configuration of the composite, as well as the concentration of copper-cysteamine. Non-limiting matrices that can substitute for polymers includes glass, transparent ceramic and transparent aluminum.

In one embodiment, the composites can comprise other electromagnetic property modulating materials. For example, CuS can be added to the copper-cysteamine/polymer admixture as a protectant against infrared damage.

In another aspect the disclosed composites can be fabricated into devices, including lamps, sheets, coverings and the like which can be configured with crops to provided enhance visible light. The enhanced visible light serves as a means for enhancing the photosynthesis of the treated crops.

### Methods

Disclosed herein are methods for utilizing the disclosed composites. In one aspect the composites provide methods for increasing the amount of visible light present when a natural or artificial source of electromagnetic radiation impinges upon the composite. In one embodiment the composite can comprise a visible light enhancing composition comprising one or more of the disclosed copper-cysteamines and a substrate. In one iteration the copper-cysteamines are deposited are deposited within a transparent substrate. In one example, the transparent substrate is the window of a structure receiving natural light from outside. In another example, the window is an opening between rooms wherein natural light and/or artificial light impinges upon the substrate thereby providing increased visible light.

In another embodiment the composite can comprise a visible light enhancing composition comprising one or more of the disclosed copper-cysteamines and a substrate wherein one surface is a reflecting surface that reflects electromagnetic radiation inward. In this embodiment radiation travels through the substrate and is reflected outward toward the source. This provides a means for enhancing the incoming, as well as the reflected radiation.

Disclosed herein is a method for providing solid state lighting having enhanced visible light, comprising:
A) exposing a composite, comprising:
   a) a visible light enhancing composition, comprising:
      i) a first copper-cysteamine that emits visible light in the range of from about 520 nm to about 700 nm when exposed to UV radiation; and
      ii) a second copper-cysteamine that emits visible light in the range of from about 400 to about 520 nm when exposed to UV radiation; and
   b) a substrate;
B) to a source of electromagnetic radiation;
wherein the electromagnetic radiation impinges upon the composite thereby increasing the amount of electromagnetic radiation in the visible range.

Also disclosed are methods for enhancing the growth of one or more plants. In a manner like the method disclosed above, the composite can be a large sheet of plastic, transparent, translucent, or otherwise allowing the transmission of visible light, which is place over growing plants. One use is to provide a covering over plants that would get reduced lighting due to the natural climate conditions or due to the reduced light due to seasonal lighting change.

In another aspect disclose herein is a method for detecting radiation, comprising:
A) exposing an article of manufacture, comprising:
   a) a composite, comprising:
   i) a first copper-cysteamine that emits visible light in the range of from about 520 nm to about 700 nm when exposed to UV radiation; and
   ii) a second copper-cysteamine that emits visible light in the range of from about 400 to about 520 nm when exposed to UV radiation; and
   b) a substrate;
B) to a source of radiation; and
C) detecting the increased amount of visible light present.

Radiation from a high energy source can be converted to radiation at longer wavelengths depending upon the selection and the concentration of copper-cysteamines. For example, the composite can have several layers of copper-cysteamine nanoparticles that capture and re-emit the electromagnetic radiation to be captured again and re-emitted at an even longer wavelength. Embodiments can be used to capture and detect X-rays and gamma-ray emissions. In a further embodiment a plurality of composites can be spaced apart wherein each composite comprises different copper-cysteamines. In one example, a vacuum is created between the layers to facilitate transmission of the re-emitted radiation onto the next layer. In another embodiment the article of manufacture is capable of being hand-held by an individual.

The present disclosure provides a description of the structure and use of non-limiting illustrative embodiments. Although certain embodiments have been described with a certain degree of particularity, or with reference to one or more individual embodiments, those skilled in the art could make numerous alterations to the disclosed embodiments without departing from the scope of this invention. As such, the various illustrative embodiments of the devices are not intended to be limited to the particular forms disclosed. Rather, they include all modifications and alternatives falling within the scope of the claims, and embodiments other than the one shown may include some or all of the features of the depicted embodiment. For example, components may be omitted or combined as a unitary structure, and/or connections may be substituted. Further, where appropriate, aspects of any of the examples described above may be combined with aspects of any of the other examples described to form further examples having comparable or different properties and addressing the same or different problems. Similarly, it will be understood that the benefits and advantages described above may relate to one embodiment or may relate to several embodiments.

What is claimed is:

1. A compound having the formula:
Cu₃X(SR)₂
wherein R is —CH₂CH₂NH₂; and
X is chosen from Br, or I.

2. The compound according to claim 1, wherein X is Br.

3. The compound according to claim 1, wherein X is I.

4. A composite, comprising:
a) a visible light enhancing composition, comprising:
i) a first copper-cysteamine that emits visible light in the range of from about 520 nm to about 700 nm when exposed to UV radiation; and
ii) a second copper-cysteamine that emits visible light in the range of from about 400 to about 520 nm when exposed to UV radiation; and
b) a substrate;
wherein the copper-cysteamine has the formula:
Cu₃X(SR)₂
wherein R is —CH₂CH₂NH₂; and
X is chosen from Cl, Br, or I.

5. The composite according to claim 4, wherein the substrate is a polymer.

6. The composite according to claim 4, wherein the substrate is a polymer chosen from polystyrene, polyethylene, polyester, polyvinyl chloride, polystyrene, or poly(methyl methacrylate).

7. The composite according to claim 4, wherein the substrate is transparent.

8. The composite according to claim 4, wherein the substrate is semi-transparent.

9. The composite according to claim 4, wherein the substrate has a first transparent surface and a second semi-transparent surface.

10. The composite according to claim 4, wherein the substrate is in the form of a film.

11. The composite according to claim 4, wherein the substrate is in the form of a geometric shape.

12. A method for providing solid state lighting having enhanced visible light, comprising;
A) exposing a composite, comprising:
a) a visible light enhancing composition, comprising:
i) a first copper-cysteamine that emits visible light in the range of from about 520 nm to about 700 nm when exposed to UV radiation; and
ii) a second copper-cysteamine that emits visible light in the range of from about 400 to about 520 nm when exposed to UV radiation; and
b) a substrate;
B) to a source of electromagnetic radiation;
wherein the copper-cysteamine has the formula:
Cu₃X(SR)₂
wherein R is —CH₂CH₂NH₂; and
X is chosen from Cl, Br, or I; and
wherein further the electromagnetic radiation impinges upon the composite thereby increasing the amount of electromagnetic radiation in the visible range.

13. The method according to claim 12 wherein the composite is a transparent opening in a structure.

14. The method according to claim 13, wherein the transparent opening comprises a polymeric material.

15. The method according to claim 13, wherein the transparent opening comprises glass.

16. A method for enhancing the growth rate of one or more plants, comprising covering the plant with:
A) exposing an article of manufacture, comprising:
a) a composite, comprising:
i) a first copper-cysteamine that emits visible light in the range of from about 520 nm to about 700 nm when exposed to UV radiation; and
ii) a second copper-cysteamine that emits visible light in the range of from about 400 to about 520 nm when exposed to UV radiation; and
b) a substrate;
B) to a source of electromagnetic radiation;
wherein the copper-cysteamine has the formula:
Cu₃X(SR)₂
wherein R is —CH₂CH₂NH₂; and
X is chosen from Cl, Br, or I; and
wherein further the electromagnetic radiation impinges upon the article of manufacture wherein the composite increases the amount of electromagnetic radiation emitted in the visible range and thereby provides for increased growth rate to the one or more plants.

17. The method according to claim 17, wherein the article of manufacture is a polymeric sheet.

18. The method according to claim 17, wherein the one or more plants is a field of crops.

19. A method for detecting radiation, comprising:
A) exposing an article of manufacture, comprising:
a) a composite, comprising:
i) a first copper-cysteamine that emits visible light in the range of from about 520 nm to about 700 nm when exposed to UV radiation; and
ii) a second copper-cysteamine that emits visible light in the range of from about 400 to about 520 nm when exposed to UV radiation; and
b) a substrate;
B) to a source of radiation; and
C) detecting the increased amount of visible light present;
wherein the copper-cysteamine has the formula:
Cu₃X(SR)₂
wherein R is —CH₂CH₂NH₂; and
X is chosen from Cl, Br, or I.

20. The method according to claim 19, wherein the article of manufacture is capable of being hand-held by an individual.
